(19) United States
(12) Patent Application Publication
(10) Pub. No.: US 2023/0086464 A1
(43) Pub. Date: Mar. 23, 2023

(54) METHOD OF SEMICONDUCTOR MANUFACTURING USING HARD MASK, METHOD FOR FORMING PATTERN, AND SEMICONDUCTOR STRUCTURE

(71) Applicant: Changxin Memory Technologies, Inc., Hefei (CN)

(72) Inventor: Meng-Cheng CHEN, HEFEI (CN)

(21) Appl. No.: 17/851,701

(22) Filed: Jun. 28, 2022

Related U.S. Application Data
(63) Continuation of application No. PCT/CN2022/087973, filed on Apr. 20, 2022.

(30) Foreign Application Priority Data
Sep. 16, 2021 (CN) 202111085413.0

(51) Int. Cl. H01L 21/308; H01L 21/311; H01L 21/033

(52) U.S. Cl. CPC H01L 21/3081; H01L 21/0332; H01L 21/31144

(57) ABSTRACT

A method of semiconductor manufacturing using a hard mask, a method for forming a pattern, and a semiconductor structure are provided. The method includes: providing a supporting base comprising a patterned sacrificial layer; forming a first protective layer covering sidewalls of the sacrificial layer; forming a first mask layer covering sidewalls of the first protective layer; removing the sacrificial layer; and removing the first protective layer from the sidewalls of the first mask layer.

### CROSS-REFERENCE TO RELATED APPLICATIONS

This application is a continuation application of International Patent Application No. PCT/CN2022/087973, filed on Apr. 20, 2022, which claims priority to Chinese Patent Application No.: 202111085413.0, titled “METHOD OF SEMICONDUCTOR MANUFACTURING USING HARD MASK, METHOD FOR FORMING PATTERN, AND SEMICONDUCTOR STRUCTURE” and filed on Sep. 16, 2021. The above-referenced applications are incorporated herein by reference in their entirety.

### TECHNICAL FIELD

The present disclosure relates to the field of semiconductor manufacturing and, in particular, to a method of semiconductor manufacturing using a hard mask, a method for forming a pattern, and a semiconductor structure.

### BACKGROUND

In the semiconductor manufacturing process, as the feature size becomes smaller and smaller and approaches the theoretical limit of an exposure system, severe distortion (due to, e.g., the optical proximity effect) may occur in patterning a silicon wafer surface via lithography. Self-aligned double patterning (SADP) technology has been developed to address this issue. The principle of self-aligned double patterning technology includes depositing around sidewalls of the first lithographed pattern after the first lithography and implementing frequency multiplication on the spatial pattern through etching.

However, in the process of depositing around sidewalls of the first lithographed pattern, silicon oxide is generally deposited on hard mask through plasma ion deposition, which may damage the hard mask. The damage to the hard mask cannot be accurately controlled, which results in uneven sizes of critical dimensions and adversely affects the yield of semiconductor devices.

Therefore, reducing the damage to the hard mask is a technical problem to be solved.

### SUMMARY

The present disclosure provides a method of semiconductor manufacturing using a hard mask, a method for forming a pattern, and a semiconductor structure, to reduce the damage to the hard mask.

One aspect of the present disclosure is directed to a method of semiconductor manufacturing using a hard mask. The method may include: providing a supporting base, the supporting base including a sacrificial layer formed on it, the sacrificial layer having a plurality of patterns; forming a first protective layer covering the sidewalls of the sacrificial layer; forming a first mask layer covering the sidewalls of the first protective layer; removing the sacrificial layer; and removing the first protective layer from the sidewalls of the first mask layer.

Another aspect of the present disclosure is directed to a method for forming a pattern. The method may include: providing a supporting base, the supporting base including a sacrificial layer formed on it, the sacrificial layer having a plurality of patterns; forming a first protective layer covering sidewalls of the sacrificial layer; forming a first mask layer covering sidewalls of the first protective layer; removing the sacrificial layer; removing the first protective layer from the sidewalls of the first mask layer; and forming a target pattern on the supporting base by using the first mask layer as a mask.

Another aspect of the present disclosure is directed to a semiconductor structure. The semiconductor structure may include: a supporting base; a patterned first protective layer, formed on the surface of the supporting base; and a patterned first mask layer covering the first protective layer and overlapping with the first protective layer when observed along a direction perpendicular to the upper surface of the supporting base.

It should be understood that the above general description and the detailed description later are only exemplary and explanatory and do not constitute a limitation on the present disclosure.

### BRIEF DESCRIPTION OF THE DRAWINGS

To explain the embodiments of the present disclosure or the technical solutions in the conventional technology more clearly, the accompanying drawings of the embodiments or the conventional technology are briefly described in the following. Apparently, the accompanying drawings in the following description only illustrate some embodiments of the present disclosure, and persons of ordinary skills in the art may derive other accompanying drawings from these accompanying drawings without creative efforts.

FIG. 1 is a schematic diagram of a method of semiconductor manufacturing using a hard mask according to an embodiment of the present disclosure.

FIG. 2 is a schematic diagram of a supporting base according to an embodiment of the present disclosure.

FIG. 3 is a schematic diagram of a first protective layer according to an embodiment of the present disclosure.

FIG. 4 is a schematic diagram of a first protective layer according to another embodiment of the present disclosure.

FIG. 5 is a schematic diagram of forming a first mask layer according to an embodiment of the present disclosure.

FIG. 6 is a schematic diagram of a first mask layer according to an embodiment of the present disclosure.

FIG. 7 is a schematic diagram of a first mask layer according to an embodiment of the present disclosure.

FIG. 8 is a schematic diagram of removing the sacrificial layer according to an embodiment of the present disclosure.

FIG. 9 is a schematic diagram of a hard mask according to an embodiment of the present disclosure.

FIG. 10 is a schematic diagram of a supporting base according to an embodiment of the present disclosure.

FIG. 11 is a schematic diagram of an initial pattern according to an embodiment of the present disclosure.

FIG. 12 is a schematic flowchart of a method for forming a pattern according to an embodiment of the present disclosure.

FIG. 13 is a schematic diagram of a substrate according to an embodiment of the present disclosure.

FIG. 14 is a schematic diagram of a target pattern according to an embodiment of the present disclosure.

FIG. 15 is a schematic diagram of a semiconductor structure according to an embodiment of the present disclosure.

FIG. 16 is a schematic diagram of a target pattern according to an embodiment of the present disclosure.

### DETAILED DESCRIPTION OF THE EMBODIMENTS

The implementations provided in the present disclosure are described in detail below in combination with the accompanying drawings.

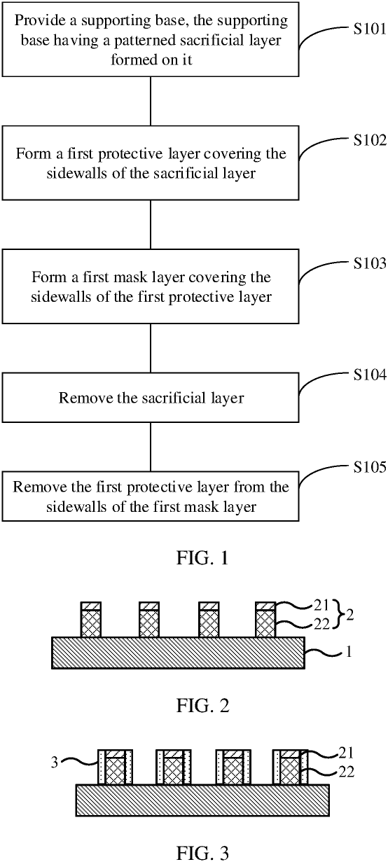

FIG. 1 is a schematic diagram of a method of semiconductor manufacturing using a hard mask according to an embodiment of the present disclosure. The method of semiconductor manufacturing using a hard mask may include the following steps S101 through S105.

In step S101, a supporting base is provided. The supporting based may include a patterned sacrificial layer (i.e., a sacrificial layer with a plurality of patterns) formed on it. In step S102, a first protective layer covering at least the sidewalls of the sacrificial layer may be formed. In step S103, a first mask layer covering the sidewalls of the first protective layer may be formed. In step S104, the sacrificial layer may be removed. In step S105, the first protective layer may be removed from the sidewalls of the first mask layer.

Referring to FIG. 1, in step S101, a supporting base with a patterned sacrificial layer formed on it may be provided. In this specification, a “patterned sacrificial layer” may refer to a sacrificial layer with a plurality of patterns. FIG. 2 is a schematic diagram of a supporting base according to an embodiment of the present disclosure. Referring to FIG. 2, a supporting base 1 with the patterned sacrificial layer 2 formed on it may be provided. In some embodiments, the sacrificial layer 2 may include a first sacrificial layer 21 and a second sacrificial layer 22. The first sacrificial layer 21 may be a silicon nitride layer, and the second sacrificial layer 22 may be a spin coated hard mask layer.

Referring to FIG. 1, in step S102, a first protective layer covering at least the sidewalls of the sacrificial layer may be formed. In some embodiments, the first protective layer may be a nitride layer. In the process of forming the first protective layer, a temperature may be 600-700° C.

FIG. 3 is a schematic diagram of a first protective layer according to an embodiment of the present disclosure. Referring to FIG. 3, in some embodiments, a first protective layer 3 covering at least the sidewalls of the first sacrificial layer 21 and the sidewalls of the second sacrificial layer 22 may be formed.

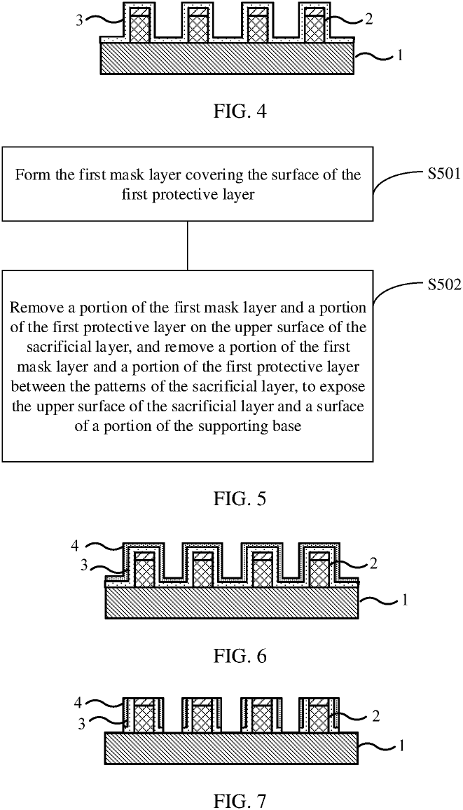

FIG. 4 is a schematic diagram of a first protective layer according to some embodiments of the present disclosure. Referring to FIG. 4, in some embodiments, in the step of forming a first protective layer 3 covering at least the sidewalls of the sacrificial layer 2, the first protective layer 3 may further cover the upper surfaces of the sacrificial layer 2 and an exposed surface of the supporting base 1.

Referring to FIG. 1, in step S103, a first mask layer covering the sidewalls of the first protective layer may be formed. In some embodiments, the first mask layer may be an oxide layer. In some embodiments, in the process of forming the first mask layer, the pressure may be 0.1-50 Torrs and the temperature may be 25-600° C. In some embodiments, raw materials for forming the first mask layer may be diisopropylaminosilane (LTO), bis(t-butylamino)silane (2NTE), or bis(diethylamino)silane (SAM-24). In some embodiments, the first mask layer may be formed through plasma-enhanced atomic deposition, thermal atomic deposition, or catalytic atomic deposition.

FIG. 5 is a schematic diagram of forming a first mask layer according to an embodiment of the present disclosure. Referring to FIG. 5, in some embodiments, the step of forming the first mask layer covering the sidewalls of the first protective layer may include the following steps S501 and S502.

In step S501, the first mask layer covering the surface of the first protective layer may be formed. In step S502, a portion of the first mask layer and a portion the first protective layer on the upper surface of the sacrificial layer may be removed to expose the upper surface of the sacrificial layer, and a portion of the first mask layer and a portion of the first protective layer between the patterns of the sacrificial layer may be removed to expose the surface of a portion of the supporting base.

In some embodiments, the portion of the first mask layer and the portion of the first protective layer on the upper surface of the sacrificial layer, and the portion of the first mask layer and the portion of the first protective layer between the patterns of the sacrificial layer may be removed by etching the first mask layer using one or more of sulfur hexafluoride, carbon tetrafluoride, chlorine, and argon.

FIG. 6 is a schematic diagram of a first mask layer according to an embodiment of the present disclosure. Referring to FIG. 6, the first mask layer 4 covering the surface of the first protective layer 3 may be formed.

FIG. 7 is a schematic diagram of a first mask layer according to some embodiments of the present disclosure. Referring to FIG. 7, a portion of the first mask layer 4 and a portion of the first protective layer 3 on the upper surface of the sacrificial layer 2 may be removed to expose the upper surface of the sacrificial layer 2, and a portion of the first mask layer 4 and a portion of the first protective layer 3 between the patterns of the sacrificial layer 2 may be removed to expose the surface of a portion of the supporting base 1. The first protective layer 3 may be formed on the sidewalls of the sacrificial layer 2 to prevent the damage to the sacrificial layer 2 when forming the first mask layer 4.

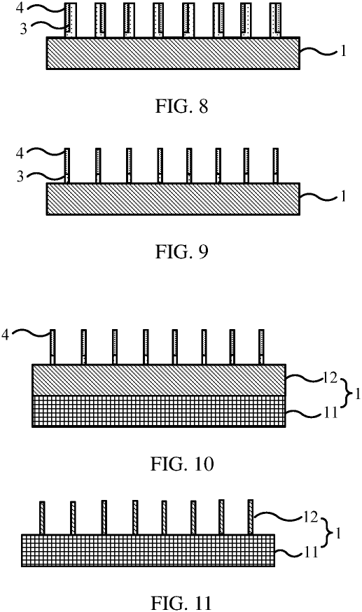

Referring to FIG. 1, in step S104, the sacrificial layer may be removed. FIG. 8 is a schematic diagram of removing the sacrificial layer according to an embodiment of the present disclosure. In this embodiment, the sacrificial layer may include a first sacrificial layer and a second sacrificial layer. After removing the first sacrificial layer and the second sacrificial layer, a portion of the first mask layer 4 and a portion of the first protective layer 3 may be retained on the supporting base 1.

Referring to FIG. 1, in step S105, the first protective layer may be removed from the sidewalls of the first mask layer. The step S105 of removing the first protective layer from the sidewalls of the first mask layer may include: etching the first protective layer downward along the sidewalls of the first mask layer to remove the first protective layer from the sidewalls of the first mask layer.

FIG. 9 is a schematic diagram of a hard mask according to an embodiment of the present disclosure. Referring to FIG. 9, the first protective layer 3 may be etched downward along the sidewalls of the first mask layer 4, and the first protective layer 3 and the first mask layer 4 retained on the supporting base 1 may be overlapped with each other when observed along a direction perpendicular to the upper surface of the supporting base, to form the hard mask.

FIG. 10 is a schematic diagram of a supporting base according to an embodiment of the present disclosure. Referring to FIG. 10, the supporting base 1 may include a substrate 11 and a second mask layer 12 disposed on the substrate 11, and an initial pattern may be formed on the second mask layer 12 by using the first mask layer 4 as a mask.

FIG. 11 is a schematic diagram of an initial pattern according to an embodiment of the present disclosure. Referring to FIG. 11, the initial pattern may be formed on the second mask layer 12 by using the first mask layer as a mask. In some embodiments, the substrate may include a semiconductor substrate and an oxide layer and a polysilicon layer disposed on the semiconductor substrate.

In the above-mentioned technical solution, the patterned sacrificial layer 2 may be formed on the supporting base 1 in step S101. The first protective layer 3 covering at least the sidewalls of the sacrificial layer 2 may be formed in step S102. The first mask layer 4 covering the sidewalls of the first protective layer 3 may be formed in step S103. The entire sacrificial layer 2 may be retained. Therefore, after the sacrificial layer 2 is removed, the position of the hard mask formed by removing the first protective layer from the sidewalls of the first mask layer may be accurate without any offset, thereby preventing uneven sizes of critical dimensions caused by the position offset of the hard mask when transferring the pattern downward, and improving the yield of semiconductor devices.

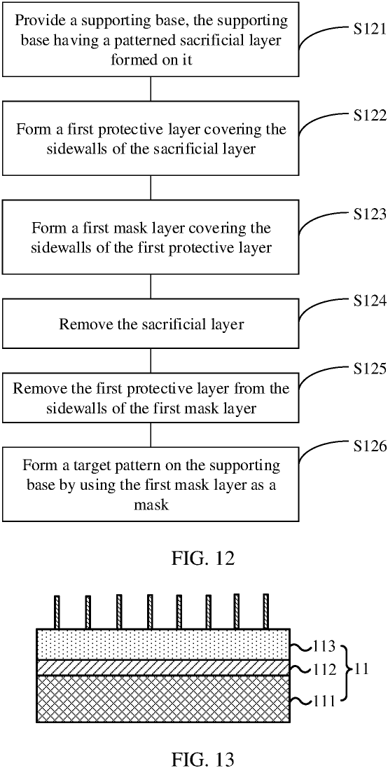

The present disclosure further provides a method for forming a pattern. FIG. 12 is a schematic flowchart of a method for forming a pattern according to an embodiment of the present disclosure. Referring to FIG. 12, the method for forming a pattern may include the following steps S121 through S126.

In step S121, a supporting base is provided. The supporting based may include a patterned sacrificial layer formed on it. In step S122, a first protective layer covering at least the sidewalls of the sacrificial layer may be formed. In step S123, a first mask layer covering the sidewalls of the first protective layer may be formed. In step S124, the sacrificial layer may be removed. In step S125, the first protective layer may be removed from the sidewalls of the first mask layer. In step S126, a target pattern may be formed on the supporting base by using the first mask layer as a mask.

Referring to FIG. 12, in step S121, a supporting base with a patterned sacrificial layer formed on it may be provided. FIG. 2 is a schematic diagram of a supporting base according to an embodiment of the present disclosure. Referring to FIG. 2, a supporting base 1 with a patterned sacrificial layer 2 formed on it may be provided. In some embodiments, the sacrificial layer 2 may include a first sacrificial layer 21 and a second sacrificial layer 22. The first sacrificial layer may be a silicon nitride layer, and the second sacrificial layer may be a spin coated hard mask layer.

Referring to FIG. 12, in step S122, the first protective layer covering at least the sidewalls of the sacrificial layer may be formed. In some embodiments, the first protective layer may be a nitride layer. In the process of forming the first protective layer, the temperature may be 600-700° C.

FIG. 3 is a schematic diagram of the first protective layer according to an embodiment of the present disclosure. Referring to FIG. 3, in some embodiments, the first protective layer 3 covering at least the sidewalls of the first sacrificial layer 21 and the sidewalls of the second sacrificial layer 22 may be formed.

FIG. 4 is a schematic diagram of the first protective layer according to some embodiments of the present disclosure. Referring to FIG. 4, in some embodiments, in the step of forming the first protective layer 3 covering at least the sidewalls of the sacrificial layer 2, the first protective layer 3 may further cover the upper surface of the sacrificial layer 2 and an exposed surface of the supporting base 1.

Referring to FIG. 12, in step S123, the first mask layer may be formed. The first mask layer may cover the sidewalls of the first protective layer. In some embodiments, the first mask layer may be an oxide layer. In some embodiments, in the process of forming the first mask layer, the pressure may be 0.1-50 Torrs and the temperature may be 25-600° C. In some embodiments, raw materials for forming the first mask layer may be diisopropylaminosilane, bis(t-butylamino)silane, or bis(diethylamino)silane. In some embodiments, the first mask layer may be formed through plasma-enhanced atomic deposition, thermal atomic deposition, or catalytic atomic deposition.

FIG. 5 is a schematic diagram of forming the first mask layer according to an embodiment of the present disclosure. Referring to FIG. 5, in some embodiments, the step of forming a first mask layer covering the sidewalls of the first protective layer may include the following steps S501 and S502. In step S501, the first mask layer covering the surface of the first protective layer may be formed. In step S502, a portion of the first mask layer and a portion of the first protective layer on the upper surface of the sacrificial layer may be removed to expose the upper surface of the sacrificial layer, and a portion of the first mask layer and a portion of the first protective layer between the patterns of the sacrificial layer may be removed to expose the surface of a portion of the supporting base. In some embodiments, the portion of the first mask layer and the portion of the first protective layer on the upper surface of the sacrificial layer, and the portion of the first mask layer and the portion of the first protective layer between the patterns of the sacrificial layer may be removed by etching the first mask layer using one or more of sulfur hexafluoride, carbon tetrafluoride, chlorine, and argon.

FIG. 6 is a schematic diagram of the first mask layer according to an embodiment of the present disclosure. Referring to FIG. 6, the first mask layer 4 covering the surface of the first protective layer 3 may be formed. FIG. 7 is a schematic diagram of the first mask layer according to an embodiment of the present disclosure. Referring to FIG. 7, a portion of the first mask layer 4 and a portion of the first protective layer 3 on the upper surface of the sacrificial layer 2 may be removed to expose the upper surface of the sacrificial layer 2, and a portion of the first mask layer 3 and a portion of the first protective layer 4 between the patterns of the sacrificial layer 2 may be removed to expose the surface of a portion of the supporting base 1. The first protective layer 3 may be formed on the sidewalls of the sacrificial layer 2 to prevent damage to the sacrificial layer when forming the first mask layer 4.

Referring to FIG. 12, in step S124, the sacrificial layer may be removed. FIG. 8 is a schematic diagram of removing the sacrificial layer according to an embodiment of the present disclosure. In some embodiments, the sacrificial layer may include a first sacrificial layer and a second sacrificial layer. After removing the first sacrificial layer and the second sacrificial layer, a portion of the first mask layer 4 and a portion of the first protective layer 3 may be retained on the supporting base 1.

Referring to FIG. 12, in step S125, the first protective layer may be removed from the sidewalls of the first mask layer. The steps of removing the first protective layer from the sidewalls of the first mask layer may include: etching the first protective layer downward along the sidewalls of the first mask layer to remove the first protection layer from the sidewalls of the first mask layer.

FIG. 9 is a schematic diagram of a hard mask according to an embodiment of the present disclosure. Referring to FIG. 9, the first protective layer 3 may be etched downward along the sidewalls of the first mask layer 4, and the first protective layer 3 and the first mask layer 4 retained on the supporting base 1 may be overlapped with each other when observed along a direction perpendicular to the upper surface of the supporting base 1, to form the hard mask.

Referring to FIG. 12, in step S126, a target pattern may be formed on the supporting based by using the first mask layer as a mask. In some embodiments, the supporting base may include a substrate and a second mask layer disposed on the substrate. The step of forming the target pattern on the supporting base by using the first mask layer as a mask may include: forming an initial pattern on the second mask layer by using the first mask layer as a mask; and transferring the initial pattern to the substrate by using the second mask layer as a mask, to form the target pattern.

FIG. 10 is a schematic diagram of a supporting base according to an embodiment of the present disclosure. Referring to FIG. 10, the supporting base 1 may include a substrate 11 and a second mask layer 12 disposed on the substrate 11. The initial pattern may be formed on the second mask layer 12 by using the first mask layer 4 as a mask.

FIG. 11 is a schematic diagram of an initial pattern according to an embodiment of the present disclosure. Referring to FIG. 11, the initial pattern may be formed on the second mask layer 12 by using the first mask layer as a mask. FIG. 13 is a schematic diagram of a substrate according to an embodiment of the present disclosure. In some embodiments, the substrate 11 may include a semiconductor substrate 111 and an oxide layer 113 and a polysilicon layer 112 disposed on the semiconductor substrate 111. The initial pattern may be transferred to the substrate by using the second mask layer on which the initial pattern is formed as a mask, to form the target pattern.

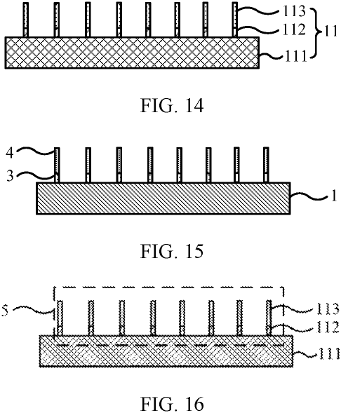

FIG. 14 is a schematic diagram of a target pattern according to an embodiment of the present disclosure. Referring to FIG. 14, the target pattern may pass through the oxide layer 113 and the polysilicon layer 112, and extend into the semiconductor substrate 111.

In the above-mentioned technical solution, the patterned sacrificial layer 2 may be formed on the supporting base in step S101. The first protective layer 3 covering at least the sidewalls of the sacrificial layer 2 may be formed in step S102. The first mask layer 4 covering the sidewalls of the first protective layer 3 may be formed in step S103. The entire sacrificial layer 2 may be retained. Therefore, after the sacrificial layer 2 is removed, the position of the hard mask formed by removing the first protective layer from the sidewalls of the first mask layer may be accurate without any offset, thereby preventing uneven sizes of critical dimensions caused by the position offset of the hard mask when transferring the pattern downward to form the target pattern, and improving the yield of semiconductor devices.

The present disclosure further provides a semiconductor structure. FIG. 15 is a schematic diagram of a semiconductor structure according to an embodiment of the present disclosure. Referring to FIG. 15, the semiconductor structure may include: a supporting base 1; a patterned first protective layer 3, formed on the surface of the supporting base 1; and a patterned first mask layer 4, covering the first protective layer 3, the first protective layer 3 overlapping with the first mask layer 4 when observed along a direction perpendicular to the upper surface of the supporting base 1.

In some embodiments, the supporting base may further include a semiconductor substrate and an oxide layer and a polysilicon layer disposed on the semiconductor substrate. The target pattern may pass through the oxide layer and the polysilicon layer, and extend into the semiconductor substrate. The supporting base may include a target pattern formed by using the first protective layer and the first mask layer as a mask. FIG. 16 is a schematic diagram of a target pattern according to an embodiment of the present disclosure. Referring to FIG. 16, the target pattern 5 may pass through the oxide layer 113 and the polysilicon layer 112, and extend into the semiconductor substrate 111.

FIG. 12 is a schematic flowchart of a method for forming a pattern according to an embodiment of the present disclosure. Referring to FIG. 12, the method for forming a pattern may include the following steps S121 through S126. In step S121, a supporting base with a patterned sacrificial layer formed on it may be provided. In step S122, a first protective layer covering at least the sidewalls of the sacrificial layer may be formed. In step S123, a first mask layer covering the sidewalls of the first protective layer may be formed. In step S124, the sacrificial layer may be removed. In step S125, the first protective layer may be removed from the sidewalls of the first mask layer. In step S126, a target pattern may be formed on the supporting base by using the first mask layer as a mask.

Referring to FIG. 12, in step S121, the supporting base with a patterned sacrificial layer formed on it may be provided. FIG. 2 is a schematic diagram of a supporting base according to an embodiment of the present disclosure. Referring to FIG. 2, the supporting base 1 with a patterned sacrificial layer 2 formed on it may be provided. In some embodiments, the sacrificial layer 2 may include a first sacrificial layer 21 and a second sacrificial layer 22. The first sacrificial layer may be a silicon nitride layer, and the second sacrificial layer may be a spin coated hard mask layer.

Referring to FIG. 12, in step S122, the first protective layer covering at least the sidewalls of the sacrificial layer may be formed. In some embodiments, the first protective layer may be a nitride layer. In the process of forming the first protective layer, the temperature may be 600-700° C.

FIG. 3 is a schematic diagram of a first protective layer according to an embodiment of the present disclosure. Referring to FIG. 3, in some embodiments, the first protective layer 3 covering at least the sidewalls of the first sacrificial layer 21 and the sidewalls of the second sacrificial layer 22 may be formed.

FIG. 4 is a schematic diagram of a first protective layer according to another embodiment of the present disclosure. Referring to FIG. 4, in some embodiments, in the step of forming a first protective layer 3 covering at least the sidewalls of the sacrificial layer 2, the first protective layer 3 may further cover the upper surface of the sacrificial layer 2 and an exposed surface of the supporting base 1.

Referring to FIG. 12, in step S123, the first mask layer covering the sidewalls of the first protective layer may be formed. In some embodiments, the first mask layer may be an oxide layer. In some embodiments, in the process of forming the first mask layer, the pressure may be 0.1-50 Torrs and the temperature may be 25-600° C. In some embodiments, raw materials for forming the first mask layer may be diisopropylaminosilane, bis(t-butylamino)silane, or bis(diethylamino)silane. In some embodiments, the first mask layer may be formed through plasma-enhanced atomic deposition, thermal atomic deposition, or catalytic atomic deposition.

FIG. 5 is a schematic diagram of forming the first mask layer according to an embodiment of the present disclosure. Referring to FIG. 5, in some embodiments, the step of forming a first mask layer covering sidewalls of the first protective layer may include the following steps S501 and S502. In step S501, the first mask layer covering the surface of the first protective layer may be formed. In step S502, a portion of the first mask layer and a portion of the first protective layer on the upper surface of the sacrificial layer may be removed to expose the upper surface of the sacrificial layer, and a portion of the first mask layer and a portion of the first protective layer between the patterns of the sacrificial layer may be removed to expose the surface of a portion of the supporting base. In some embodiments, the portion of the first mask layer and the portion of the first protective layer on the upper surface of the sacrificial layer, and the portion of the first mask layer and the portion of the first protective layer between the patterns of the sacrificial layer may be removed by etching the first mask layer using one or more of sulfur hexafluoride, carbon tetrafluoride, chlorine, and argon.

FIG. 6 is a schematic diagram of a first mask layer according to an embodiment of the present disclosure. Referring to FIG. 6, the first mask layer 4 covering the surface of the first protective layer 3 may be formed. FIG. 7 is a schematic diagram of the first mask layer according to an embodiment of the present disclosure. Referring to FIG. 7, a portion of the first mask layer 4 and a portion of the first protective layer 3 on the upper surface of the sacrificial layer 2 may be removed to expose the upper surface of the sacrificial layer 2. A portion of the first mask layer 3 and a portion of the first protective layer 4 between the patterns of the sacrificial layer 2 may be removed to expose the surface of a portion of the supporting base 1. The first protective layer 3 may be formed on the sidewalls of the sacrificial layer 2 to prevent damage to the sacrificial layer when forming the first mask layer 4.

Referring to FIG. 12, in step S124, the sacrificial layer may be removed. FIG. 8 is a schematic diagram of removing the sacrificial layer according to an embodiment of the present disclosure. In some embodiments, the sacrificial layer may include a first sacrificial layer and a second sacrificial layer. After removing the first sacrificial layer and the second sacrificial layer, a portion of the first mask layer 4 and the first protective layer 3 may be retained on the supporting base 1.

Referring to FIG. 12, in step S125, the first protective layer may be removed from the sidewalls of the first mask layer. The step of removing the first protective layer from the sidewalls of the first mask layer may include: etching the first protective layer downward along the sidewalls of the first mask layer to remove the first protective layer from the sidewalls of the first mask layer.

FIG. 9 is a schematic diagram of a hard mask according to an embodiment of the present disclosure. Referring to FIG. 9, the first protective layer 3 may be etched downward along the sidewalls of the first mask layer 4, and the first protective layer 3 and the first mask layer 4 retained on the supporting base 1 may be overlapped with each other when observed along a direction perpendicular to the upper surface of the supporting base 1, to form the hard mask.

Referring to FIG. 12, in step S126, a target pattern may be formed on the supporting based by using the first mask layer as a mask. In some embodiments, the supporting base may include a substrate and a second mask layer disposed on the substrate. The steps of forming a target pattern on the supporting base by using the first mask layer as a mask may include: forming an initial pattern on the second mask layer by using the first mask layer as a mask; and transferring the initial pattern to the substrate by using the second mask layer as a mask, to form the target pattern.

In the above-mentioned technical solution, by forming a patterned sacrificial layer 2 on the supporting base, forming a first protective layer 3 covering at least the sidewalls of the sacrificial layer 2, and forming a first mask layer 4 covering the sidewalls of the first protective layer 3, the entire sacrificial layer 2 may be retained. Therefore, after the sacrificial layer 2 is removed, the position of the hard mask formed by removing the first protective layer from the sidewalls of the first mask layer may be accurate without any offset, thereby preventing uneven sizes of critical dimensions caused by the position offset of the hard mask when transferring the pattern downward to form the target pattern, and improving the yield of semiconductor devices.

The above are only the preferred implementations of the present disclosure. It should be noted that those of ordinary skilled in the art may make modifications and improvements without departing from the principles of the present disclosure, which should be regarded as falling within the scope of protection of the present disclosure.

What is claimed is:

1. A method of semiconductor manufacturing using a hard mask, comprising:
providing a supporting base with a sacrificial layer formed on the supporting base, the sacrificial layer having a plurality of patterns;
forming a first protective layer covering sidewalls of the sacrificial layer;
forming a first mask layer covering sidewalls of the first protective layer;
removing the sacrificial layer; and
removing the first protective layer from sidewalls of the first mask layer.

2. The method of claim 1, wherein, when forming the first protective layer covering the sidewalls of the sacrificial layer, the first protective layer further covers an upper surface of the sacrificial layer and an exposed surface of the supporting base, and wherein forming the first mask layer covering the sidewalls of the first protective layer comprises:
forming the first mask layer covering a surface of the first protective layer; and
removing the first mask layer and the first protective layer on the upper surface of the sacrificial layer to expose the upper surface of the sacrificial layer, and
removing a portion of the first mask layer and a portion of the first protective layer between the patterns of the sacrificial layer to expose a surface of a portion of the supporting base.

3. The method of claim 1, wherein the removing the first protective layer from the sidewalls of the first mask layer comprises:
etching the first protective layer downward along the sidewalls of the first mask layer to remove the first protective layer from the sidewalls of the first mask layer.

4. The method of claim 1, wherein the supporting base comprises a substrate and a second mask layer disposed on the substrate, and the method further comprises:
forming an initial pattern on the second mask layer by using the first mask layer as a mask.

5. The method of claim 4, wherein the substrate comprises a semiconductor substrate and an oxide layer and a polysilicon layer disposed on the semiconductor substrate.

6. The method of claim 1, wherein the first protective layer is a nitride layer.

7. The method of claim 1, wherein the first mask layer is an oxide layer.

8. The method of claim 1, wherein the first protective layer is formed in a temperature of 600-700° C.

9. The method of claim 1, wherein the first mask layer is formed under a pressure of 0.1-50 Torrs and a temperature of 25-600° C.

10. The method of claim 1, wherein the first mask layer is made of diisopropylaminosilane, bis(t-butylamino)silane, or bis(diethylamino)silane.

11. The method of claim 1, wherein the first mask layer is formed through plasma-enhanced atomic deposition, thermal atomic deposition, or catalytic atomic deposition.

12. The method of claim 2, wherein the portion of the first mask layer, the portion of the first protective layer on the upper surface of the sacrificial layer, the portion of the first mask layer and the portion of the first protective layer between the patterns of the sacrificial layer are removed by etching the first mask layer using one or more of sulfur hexafluoride, carbon tetrafluoride, chlorine, and argon.

13. A method for forming a pattern, comprising:
providing a supporting base, the supporting base comprising a sacrificial layer formed on it, the sacrificial layer having a plurality of patterns;
forming a first protective layer covering sidewalls of the sacrificial layer;
forming a first mask layer covering sidewalls of the first protective layer;
removing the sacrificial layer;
removing the first protective layer from sidewalls of the first mask layer; and
forming a target pattern on the supporting base by using the first mask layer as a mask.

14. The method of claim 13, wherein, when forming the first protective layer covering the sidewalls of the sacrificial layer, the first protective layer further covers an upper surface of the sacrificial layer and an exposed surface of the supporting base, and wherein forming the first mask layer covering the sidewalls of the first protective layer comprises:
forming the first mask layer covering a surface of the first protective layer; and
removing a portion of the first mask layer and a portion of the first protective layer on the upper surface of the sacrificial layer to expose the upper surface of the sacrificial layer; and
removing a portion of the first mask layer and a portion of the first protective layer between the patterns of the sacrificial layer to expose a surface of a portion of the supporting base.

15. The method of claim 13, wherein removing the first protective layer from the sidewalls of the first mask layer comprises:
etching the first protective layer downward along the sidewalls of the first mask layer to remove the first protective layer from the sidewalls of the first mask layer.

16. The method of claim 13, wherein the supporting base comprises a substrate and a second mask layer disposed on the substrate, and forming the target pattern on the supporting base by using the first mask layer as a mask comprises:
forming an initial pattern on the second mask layer by using the first mask layer as the mask; and
transferring the initial pattern to the substrate by using the second mask layer as a mask, to form the target pattern.

17. The method of claim 16, wherein the substrate comprises a semiconductor substrate and an oxide layer and a polysilicon layer disposed on the semiconductor substrate, and the target pattern passes through the oxide layer and the polysilicon layer, and extends into the semiconductor substrate.

18. A semiconductor structure, comprising:
a supporting base;
a patterned first protective layer formed on a surface of the supporting base; and
a patterned first mask layer covering the first protective layer and overlapping with the first protective layer when observed along a direction perpendicular to an upper surface of the supporting base.

19. The semiconductor structure of claim 18, wherein the supporting base comprises a target pattern formed by using the first protective layer and the first mask layer as a mask.

20. The semiconductor structure of claim 19, wherein the supporting base further comprises a semiconductor substrate and an oxide layer and a polysilicon layer disposed on the semiconductor substrate, and the target pattern passes through the oxide layer and the polysilicon layer, and extends into the semiconductor substrate.
